(19) United States
(12) Patent Application Publication
(10) Pub. No.: US 2019/0391490 A1
(43) Pub. Date: Dec. 26, 2019

(54) NEGATIVE PHOTOSENSITIVE COMPOSITION, ARTICLE CURED THEREFROM, AND METHOD FOR CURING SAID COMPOSITION

(71) Applicant: ADEKA CORPORATION, Tokyo (JP)

(72) Inventors: Taiki MIHARA, Tokyo (JP); Junya MIYAKE, Tokyo (JP); Naomi SATO, Tokyo (JP)

(73) Assignee: ADEKA CORPORATION, Tokyo (JP)

(21) Appl. No.: 16/465,113

(22) PCT Filed: Nov. 29, 2017
(86) PCT No.: PCT/JP2017/042877

§ 371 Date: May 29, 2019

(30) Foreign Application Priority Data
Nov. 30, 2016 (JP) 2016-233520

(51) Int. Cl. G03F 7/027; C08K 5/42; C08L 61/28; C08L 25/04; C08L 33/04; G03F 7/038; G03F 7/20

(52) U.S. Cl. CPC G03F 7/027; C08K 5/42; C08L 61/28; G03F 7/20; C08L 33/04; G03F 7/038; C08L 25/04

(57) ABSTRACT

Provided are: a negative photosensitive composition which exhibits excellent sensitivity at the time of being cured and yields a cured article having excellent heat resistance; a cured article thereof; and a method of curing the same. The negative photosensitive composition contains: a sulfonic acid derivative compound (A) represented by Formula (I) below where X¹ represents a linear or branched alkyl group having 1 to 14 carbon atoms or the like; R¹ represents an aliphatic hydrocarbon group having 1 to 18 carbon atoms or the like; and the aliphatic hydrocarbon group having 1 to 18 carbon atoms or the like has no substituent or is optionally substituted with a halogen atom or a group selected from a halogenated alkyl group having 1 to 4 carbon atoms, an alkoxy group having 1 to 18 carbon atoms and an alkylthio group having 1 to 18 carbon atoms; a crosslinkable functional group-containing polymer compound (B); and a crosslinking agent (C):

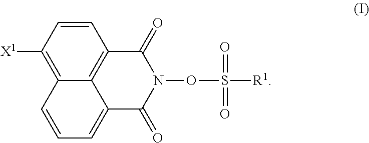

### TECHNICAL FIELD

The present invention relates to: a negative photosensitive composition (hereinafter, also simply referred to as “composition”); a cured article thereof; and a method of curing the same. More particularly, the present invention relates to: a negative photosensitive composition which exhibits excellent sensitivity at the time of being cured and yields a cured article having excellent heat resistance; a cured article thereof; and a method of curing the same.

### BACKGROUND ART

Sulfonyloxyimides having a naphthalimino group which is a radioactive functional group are substances that generate an acid when irradiated with an energy beam such as light, and they are used as, for example, photoacid generators contained in photolithography resist compositions used for the formation of an electronic circuit such as a semiconductor, and as cationic polymerization initiators contained in photopolymerizable compositions such as resin compositions for stereolithography, paints, coatings, adhesives, and inks.

For example, Patent Documents 1 to 5 propose negative resists in which various alkali-soluble resins, acid generators such as onium salts and oxium sulfonate compounds, and crosslinking agents are used.

### RELATED ART DOCUMENTS

### Patent Documents

[Patent Document 1] JP2000-347392A

[Patent Document 2] JP2006-317602A

[Patent Document 3] JP2008-209948A

[Patent Document 4] JP2013-140338A

[Patent Document 5] JP4401033B2

### SUMMARY OF THE INVENTION

### Problems to be Solved by the Invention

However, in Patent Documents 1 to 5, high sensitivity in curing and high heat resistance of cured articles cannot be satisfied at the same time, and there is thus room further investigation. Moreover, cure shrinkage is also an important property in curable compositions.

In view of the above, an object of the present invention is to provide: a negative photosensitive composition which exhibits excellent sensitivity at the time of being cured and yields a cured article having excellent heat resistance; a cured article thereof; and a method of curing the same.

### Means for Solving the Problems

The present inventors intensively studied to solve the above-described problem and consequently discovered that the problem can be solved by using a sulfonic acid derivative compound having a specific structure and a specific polymer compound, thereby completing the present invention.

That is, a negative photosensitive composition of the present invention is characterized by containing:

a sulfonic acid derivative compound (A) represented by the following Formula (IT

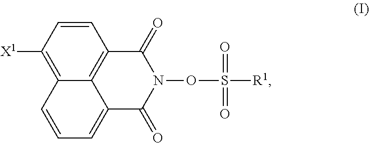

where X¹ represents a linear or branched alkyl group having 1 to 14 carbon atoms; a methylene group in the alkyl group is optionally substituted with —S—, —O—, —SO— or —SO₂—; R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the following Formula (II):

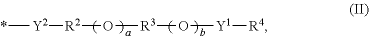

where Y¹ represents a single bond or an alkanediyl group having 1 to 4 carbon atom, Y² represents a single bond, a sulfur atom, or an oxygen atom; R² and R³ each independently represent an alkanediyl group having 2 to 6 carbon atoms, a halogenated alkanediyl group having 1 to 6 carbon atoms, an arylene group having 6 to 20 carbon atoms, or a halogenated arylene group having 6 to 20 carbon atoms; R⁴ represents a linear or branched alkyl group having 1 to 18 carbon atoms, a linear or branched halogenated alkyl group having 1 to 18 carbon atoms, an alicyclic hydrocarbon group having 3 to 12 carbon atoms, an aryl group having 6 to 20 carbon atoms, a halogenated aryl group having 6 to 20 carbon atoms, an arylalkyl group having 7 to 20 carbon atoms, or a halogenated arylalkyl group having 7 to 20 carbon atoms; a and b each represent 0 or 1; either a or b is 1; and the asterisk “*” indicates that this group is bound with an adjacent group at the * part; and

the aliphatic hydrocarbon group having 1 to 18 carbon atoms, the aryl group having 6 to 20 carbon atoms, the arylalkyl group having 7 to 20 carbon atoms or the alicyclic hydrocarbon group having 3 to 12 carbon atoms has no substituent, or is optionally substituted with a halogen atom or a group selected from a halogenated alkyl group having 1 to 4 carbon atoms, an alkoxy group having 1 to 18 carbon atoms and an alkylthio group having 1 to 18 carbon atoms;

a crosslinkable functional group-containing polymer compound (B); and

a crosslinking agent (C).

In the composition of the present invention, X¹ is preferably an alkyl group having 4 carbon atoms. Further, in the composition of the present invention, R¹ is preferably a perfluoroalkyl group having 1 to 8 carbon atoms. Further, in the composition of the present invention, the crosslinkable functional group-containing polymer compound (B) is preferably a polyhydroxystyrene resin, an epoxy resin, an epoxy acrylate resin or epoxy methacrylate resin that has at least one substituent selected from a hydroxy group and a carboxyl group, or a novolac resin having a hydroxy group, an epoxy group or a carboxyl group.

In the composition of the present invention, the crosslinkable functional group-containing polymer compound (B) is preferably a polyhydroxystyrene resin required to contain a structural unit represented by the following Formula (III); an epoxy acrylate resin or epoxy methacrylate resin that has a structure in which acrylic acid or methacrylic acid is added to a polyfunctional epoxy resin; or an epoxy acrylate resin or epoxy methacrylate resin that is obtained by an esterification reaction between a polybasic acid anhydride and an epoxy adduct having a structure in which acrylic acid or methacrylic acid is added to a polyfunctional epoxy resin:

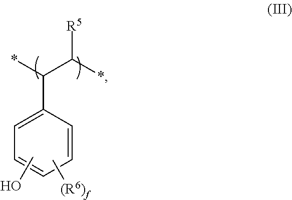

where R⁵ represents a hydrogen atom or a methyl group; R⁶ represents an alkyl group having 1 to 4 carbon atoms, an alkoxy group having 1 to 4 carbon atoms, or an alkoxycarbonyl group having 2 to 4 carbon atoms; f represents a number of 0 to 4; and the asterisks “*” indicate that this group is bound with adjacent groups at the * part. Further, in the composition of the present invention, the crosslinking agent (C) is preferably a melamine resin.

A cured article of the present invention is characterized in that it is obtained by curing the negative photosensitive composition of the present invention.

A curing method of the present invention is characterized by including curing the negative photosensitive composition of the present invention by irradiating thereto heat or light.

### Effects of the Invention

According to the present invention, a negative photosensitive composition which exhibits excellent sensitivity at the time of being cured and yields a cured article having excellent heat resistance, a cured article thereof, and a method of curing the same can be provided.

### MODE FOR CARRYING OUT THE INVENTION

The present invention will now be described in detail based on embodiments thereof.

The negative photosensitive composition of the present invention contains: a sulfonic acid derivative compound (A) represented by Formula (I) below; a crosslinkable functional group-containing polymer compound (B) (hereinafter, also referred to as “polymer compound (B)”); and a crosslinking agent (C):

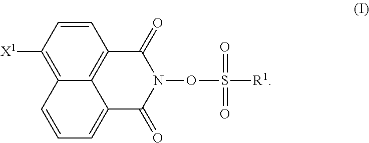

This composition is advantageous in that it exhibits excellent sensitivity at the time of being cured, yields a cured article excellent heat resistance, and has a small cure shrinkage.

In Formula (I), X¹ represents a linear or branched alkyl group having 1 to 14 carbon atoms; a methylene group in the alkyl group is optionally substituted with —S—, —O—, —SO— or —SO₂—; R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the following Formula (II):

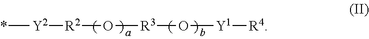

The aliphatic hydrocarbon group having 1 to 18 carbon atoms, the aryl group having 6 to 20 carbon atoms, the arylalkyl group having 7 to 20 carbon atoms or the alicyclic hydrocarbon group having 3 to 12 carbon atoms has no substituent, or is substituted with a halogen atom or a group selected from a halogenated alkyl group having 1 to 4 carbon atoms, an alkoxy group having 1 to 18 carbon atoms and an alkylthio group having 1 to 18 carbon atoms.

In Formula (II), Y¹ represents a single bond or an alkanediyl group having 1 to 4 carbon atoms; Y² represents a single bond, a sulfur atom, or an oxygen atom; R² and R³ each independently represent an alkanediyl group having 2 to 6 carbon atoms, a halogenated alkanediyl group having 1 to 6 carbon atoms, an arylene group having 6 to 20 carbon atoms, or a halogenated arylene group having 6 to 20 carbon atoms; R⁴ represents a linear or branched alkyl group having 1 to 18 carbon atoms, a linear or branched halogenated alkyl group having 1 to 18 carbon atoms, an alicyclic hydrocarbon group having 3 to 12 carbon atoms, an aryl group having 6 to 20 carbon atoms, a halogenated aryl group having 6 to 20 carbon atoms, an arylalkyl group having 7 to 20 carbon atoms, or a halogenated arylalkyl group having 7 to 20 carbon atoms; a and b each represent 0 or 1; and either a or b is 1.

<Sulfonic Acid Derivative Compound (A)>

In Formula (I), X¹ represents a linear or branched alkyl group having 1 to 14 carbon atoms. Examples thereof include methyl, ethyl, propyl, isopropyl, 1-butyl, 2-butyl, isobutyl, tert-butyl, 1-pentyl, isopentyl, tert-pentyl, neopentyl, 1-hexyl, 2-hexyl, 3-hexyl, heptyl, 2-heptyl, 3-heptyl, isoheptyl, tert-heptyl, 1-octyl, isooctyl, tert-octyl, 2-ethylhexyl, 1-nonyl, isononyl, 1-decyl, 1-dodecyl, tridecyl, and tetradecyl. Thereamong, an alkyl group having 3 to 8 carbon atoms is preferred and an alkyl group having 4 carbon atoms is more preferred since these alkyl groups have both good solubility and good acid generation rate. A 1-butyl group is still more preferred since the material thereof is inexpensive and has good yield and low production cost. Further, the alkyl group is preferably an unsubstituted alkyl group.

In Formula (I), R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the above-described Formula (II). Among these groups, the aliphatic hydrocarbon group, the aryl group, the arylalkyl group and the alicyclic hydrocarbon group optionally do not have any substituent, or are optionally substituted with a halogen atom or a group selected from a halogenated alkyl group having 1 to 4 carbon atoms, an alkoxy group having 1 to 18 carbon atoms and an alkylthio group having 1 to 18 carbon atoms.

Examples of the halogen atom which is a substituent include chlorine, bromine, iodine, and fluorine.

Examples of the halogenated alkyl group having 1 to 4 carbon atoms which is a substituent include a trifluoromethyl group.

Examples of the alkoxy group having 1 to 18 carbon atoms which is a substituent include methoxy, ethoxy, propoxy, butoxy, tert-butoxy, pentyloxy, hexyloxy, heptyloxy, octyloxy, nonyloxy, decyloxy, undecyloxy, dodecyloxy, tridecyloxy, tetradecyloxy, pentadecyloxy, hexadecyloxy, heptadecyloxy, and octadecyloxy.

Examples of the alkylthio group having 1 to 18 carbon atoms which is a substituent include methylthio, ethylthio, propylthio, isopropylthio, butylthio, sec-butylthio, tert-butylthio, isobutylthio, amylthio, isoamylthio, tert-amylthio, hexylthio, heptylthio, isoheptylthio, tert-heptylthio, octylthio, isooctylthio, tert-octylthio, 2-ethylhexylthio, nonylthio, decylthio, undecylthio, dodecylthio, tridecylthio, tetradecylthio, pentadecylthio, hexadecylthio, heptadecylthio, and octadecylthio.

Examples of the aliphatic hydrocarbon group having 1 to 18 carbon atoms that may be represented by R¹ include an alkenyl group, an alkyl group, an alkyl group in which a methylene group is substituted with an alicyclic hydrocarbon group, an alkyl group in which a proton of a methylene group is substituted with an alicyclic hydrocarbon group, and an alkyl group in which an alicyclic hydrocarbon exists at a terminal.

Examples of the alkenyl group include allyl and 2-methyl-2-propenyl.

Examples of the alkyl group include methyl, ethyl, propyl, isopropyl, butyl, sec-butyl, tert-butyl, isobutyl, amyl, isoamyl, tert-amyl, hexyl, 2-hexyl, 3-hexyl, heptyl, 2-heptyl, 3-heptyl, isoheptyl, tert-heptyl, octyl, isooctyl, tert-octyl, 2-ethylhexyl, nonyl, isononyl, decyl, dodecyl, tridecyl, tetradecyl, pentadecyl, hexadecyl, heptadecyl, and octadecyl.

Examples of the alicyclic hydrocarbon group include, stating them in terms of the names of cycloalkanes constituting the respective alicyclic hydrocarbon groups: cyclopropane, cyclobutane, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

Examples of the aliphatic hydrocarbon group having 1 to 18 carbon atoms that is substituted with a halogen atom and may be represented by R¹ include halogenated alkyl groups, such as trifluoromethyl, pentafluoroethyl, 2-chloroethyl, 2-bromoethyl, heptafluoropropyl, 3-bromopropyl, nonafluorobutyl, tridecafluorohexyl, heptadecafluorooctyl, 2,2,2-trifluoroethyl, 1,1-difluoroethyl, 1,1-difluoropropyl, 1,1,2,2-tetrafluoropropyl, 3,3,3-trifluoropropyl, 2,2,3,3,3-pentafluoropropyl, norbornyl-1,1-difluoroethyl, norbornyltetrafluoroethyl, adamantane-1,1,2,2-tetrafluoropropyl, and bicyclo[2.2.1]heptane-tetrafluoromethyl.

Examples of the aliphatic hydrocarbon group having 1 to 18 carbon atoms that is substituted with an alkoxy group having 1 to 18 carbon atoms and may be represented by R¹ include a methoxymethyl group, a methoxyethyl group, a methoxypropyl group, a methoxybutyl group, a butoxymethyl group, an ethoxyethyl group, an ethoxypropyl group, and a propoxybutyl group.

Examples of the aliphatic hydrocarbon group having 1 to 18 carbon atoms that is substituted with an alkylthio group having 1 to 18 carbon atoms and may be represented by R¹ include 2-methylthioethyl, 4-methylthiobutyl and 4-butylthioethyl, and examples of the aliphatic hydrocarbon having 1 to 18 carbon atoms that is substituted with both a halogen atom and an alkylthio group having 1 to 18 carbon atoms include 1,1,2,2-tetrafluoro-3-methylthiopropyl.

Examples of the aryl group having 6 to 20 carbon atoms that may be represented by R¹ include phenyl, naphthyl, 2-methylphenyl, 3-methylphenyl, 4-methylphenyl, 4-vinylphenyl, 3-isopropylphenyl, 4-isopropylphenyl, 4-butylphenyl, 4-isobutylphenyl, 4-tert-butylphenyl, 4-hexylphenyl, 4-cyclohexylphenyl, 4-octylphenyl, 4-(2-ethylhexyl)phenyl, 2,3-dimethylphenyl, 2,4-dimethylphenyl, 2,5-dimethylphenyl, 2,6-dimethylphenyl, 3,4-dimethylphenyl, 3,5-dimethylphenyl, 2,4-di-tert-butylphenyl, 2,5-di-tert-butylphenyl, 2,6-di-tert-butylphenyl, 2,4-di-tert-pentylphenyl, 2,5-di-tert-amylphenyl, 2,5-di-tert-octylphenyl, cyclohexylphenyl, biphenyl, 2,4,5-trimethylphenyl, 2,4,6-trimethylphenyl, and 2,4,6-triisopropylphenyl.

Examples of the aryl group having 6 to 20 carbon atoms that is substituted with a halogen atom and may be represented by R¹ include pentafluorophenyl, chlorophenyl, dichlorophenyl, trichlorophenyl, 2,4-bis(trifluoromethyl)phenyl, and bromoethylphenyl.

Examples of the aryl group having 6 to 20 carbon atoms that is substituted with an alkoxy group having 1 to 18 carbon atoms and may be represented by R¹ include 2-methoxyphenyl and 2,4-dimethoxyphenyl.

Examples of the aryl group having 6 to 20 carbon atoms that is substituted with an alkylthio group having 1 to 18 carbon atoms and may be represented by R¹ include 4-methylthiophenyl, 4-butylthiophenyl, 4-octylthiophenyl, and 4-dodecylthiophenyl. Examples of the aryl group having 6 to 20 carbon atoms that is substituted with both a halogen atom and an alkylthio group having 1 to 18 carbon atoms include 1,2,5,6-tetrafluoro-4-methylthiophenyl, 1,2,5,6-tetrafluoro-4-butylthiophenyl, and 1,2,5,6-tetrafluoro-4-dodecylthiophenyl.

Examples of the arylalkyl group having 7 to 20 carbon atoms that may be represented by R¹ include benzyl, phenethyl, 2-phenylpropan-2-yl, diphenylmethyl, triphenylmethyl, styryl, and cinnamyl.

Examples of the arylalkyl group having 7 to 20 carbon atoms that is substituted with a halogen atom and may be represented by R¹ include pentafluorophenylmethyl, phenyldifluoromethyl, 2-phenyl-tetrafluoroethyl, and 2-(pentafluorophenyl)ethyl.

Examples of the arylalkyl group having 7 to 20 carbon atoms that is substituted with an alkoxy group having 1 to 18 carbon atoms and may be represented by R¹ include methoxybenzyl, dimethoxybenzyl, and ethoxybenzyl.

Examples of the arylalkyl group having 7 to 20 carbon atoms that is substituted with an alkylthio group having 1 to 18 carbon atoms and may be represented by R¹ include p-methylthiobenzyl. Examples of the arylalkyl group having 7 to 20 carbon atoms that is substituted with both a halogen atom and an alkylthio group having 1 to 18 carbon atoms include 2,3,5,6-tetrafluoro-4-methylthiophenylethyl.

The number of carbon atoms of the acyl group-substituted aryl group having 7 to 20 carbon atoms that may be represented by R¹ includes the carbon atoms of the acyl group.

Examples of such an aryl group include acetylphenyl, acetylnaphthyl, benzoylphenyl, 1-anthraquinolyl, and 2-anthraquinolyl.

Examples of the alicyclic hydrocarbon group having 3 to 12 carbon atoms that may be represented by R¹ include, stating them in terms of the names of cycloalkanes constituting the respective alicyclic hydrocarbon groups: cyclopropane, cyclobutane, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

Formula (II) is a group having at least one ether bond. In Formula (II), examples of the alkanediyl group having 1 to 4 carbon atoms that may be represented by Y¹ include methylene, ethylene, propane-1,3-diyl, propane-1,2-diyl, butylene, butane-1,3-diyl, butane-2,3-diyl, and butane-1,2-diyl. Further, Y² represents a single bond, a sulfur atom, or an oxygen atom.

Examples of the alkanediyl group having 2 to 6 carbon atoms that may be represented by R² and R³ include ethylene, propane-1,3-diyl, propane-1,2-diyl, butylene, butane-1,3-diyl, butane-2,3-diyl, butane-1,2-diyl, pentane-1,5-diyl, pentane-1,3-diyl, pentane-1,4-diyl, pentane-2,3-diyl, hexane-1,6-diyl, hexane-1,2-diyl, hexane-1,3-diyl, hexane-1,4-diyl, hexane-2,5-diyl, hexane-2,4-diyl, and hexane-3,4-diyl.

The halogenated alkanediyl group having 1 to 6 carbon atoms that may be represented by R² and R³ is any one of the above-described alkanediyl groups having 2 to 6 carbon atoms in which at least one proton is substituted with a halogen atom. Examples of the halogen atom include chlorine, bromine, iodine, and fluorine. Examples of the halogenated alkanediyl group having 1 to 6 carbon atoms include tetrafluoroethylene, 1,1-difluoroethylene, 1-fluoroethylene, 1,2-difluoroethylene, hexafluoropropane-1,3-diyl, 1,1,2,2-tetrafluoropropane-1,3-diyl, and 1,1,2,2-tetrafluoropentane-1,5-diyl.

Examples of the arylene group having 6 to 20 carbon atoms that may be represented by R² and R³ include 1,2-phenylene, 1,3-phenylene, 1,4-phenylene, 2,5-dimethyl-1,4-phenylene, 4,4′-biphenylene, diphenylmethane-4,4′-diyl, 2,2-diphenylpropane-4,4′-diyl, naphthalene-1,2-diyl, naphthalene-1,3-diyl, naphthalene-1,4-diyl, naphthalene-1,5-diyl, naphthalene-1,6-diyl, naphthalene-1,7-diyl, naphthalene-1,8-diyl, naphthalene-2,3-diyl, naphthalene-2,6-diyl, and naphthalene-2,7-diyl.

The halogenated arylene group having 6 to 20 carbon atoms that may be represented by R² and R³ is any one of the above-described arylene groups having 6 to 20 carbon atoms in which at least one proton is substituted with a halogen atom. Examples of the halogen atom include chlorine, bromine, iodine, and fluorine. Examples of the halogenated arylene group having 6 to 20 carbon atoms include tetrafluorophenylene.

Examples of the alkyl group having 1 to 18 carbon atoms that may be represented by R⁴ include methyl, ethyl, propyl, isopropyl, butyl, sec-butyl, tert-butyl, isobutyl, amyl, isoamyl, tert-amyl, hexyl, 2-hexyl, 3-hexyl, heptyl, 2-heptyl, 3-heptyl, isoheptyl, tert-heptyl, octyl, isooctyl, tert-octyl, 2-ethylhexyl, nonyl, isononyl, decyl, dodecyl, tridecyl, tetradecyl, pentadecyl, hexadecyl, heptadecyl, and octadecyl.

The halogenated alkyl group having 1 to 18 carbon atoms that may be represented by R⁴ is any one of the above-described alkyl groups having 1 to 18 carbon atoms in which at least one proton is substituted with a halogen atom. Examples of the halogen atom include chlorine, bromine, iodine, and fluorine. Examples of the halogenated alkyl group having 1 to 18 carbon atoms include halogenated alkyl groups, such as trifluoromethyl, pentafluoroethyl, heptafluoropropyl, nonafluorobutyl, tridecafluorohexyl, heptadecafluorooctyl, 2,2,2-trifluoroethyl, 1,1-difluoroethyl, 1,1-difluoropropyl, 1,1,2,2-tetrafluoropropyl, 3,3,3-trifluoropropyl, 2,2,3,3,3-pentafluoropropyl, and 1,1,2,2-tetrafluorotetradecyl.

Examples of the alicyclic hydrocarbon group having 3 to 12 carbon atoms that may be represented by R⁴ include, stating them in terms of the names of cycloalkanes constituting the respective alicyclic hydrocarbon groups: cyclopropane, cyclobutane, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

Examples of the aryl group having 6 to 20 carbon atoms, halogenated aryl group having 6 to 20 carbon atoms, arylalkyl group having 7 to 20 carbon atoms or halogenated arylalkyl group having 7 to 20 carbon atoms that may be represented by R⁴ include the same groups as those exemplified above for R¹.

A group preferred as Formula (II) is a group having a total of 2 to 18 carbon atoms in which fluorine is bound to a carbon atom of a group represented by R² that is adjacent to a sulfur atom since such a group has good acid generation capacity, cationic polymerizability and the like. Specific examples of the sulfonic acid derivative compound (A) used in the present invention include the following Compound Nos. 1 to 47:

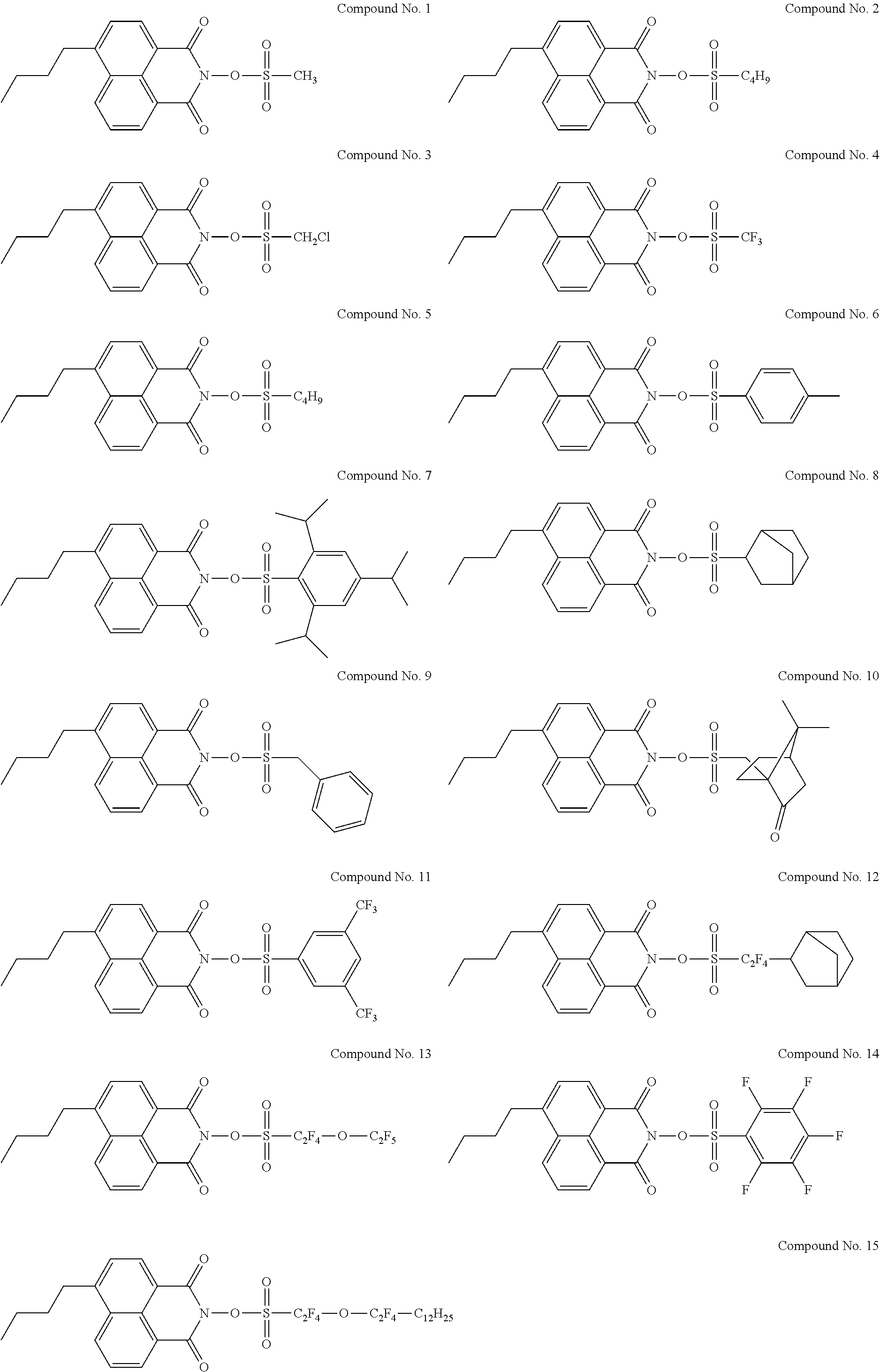

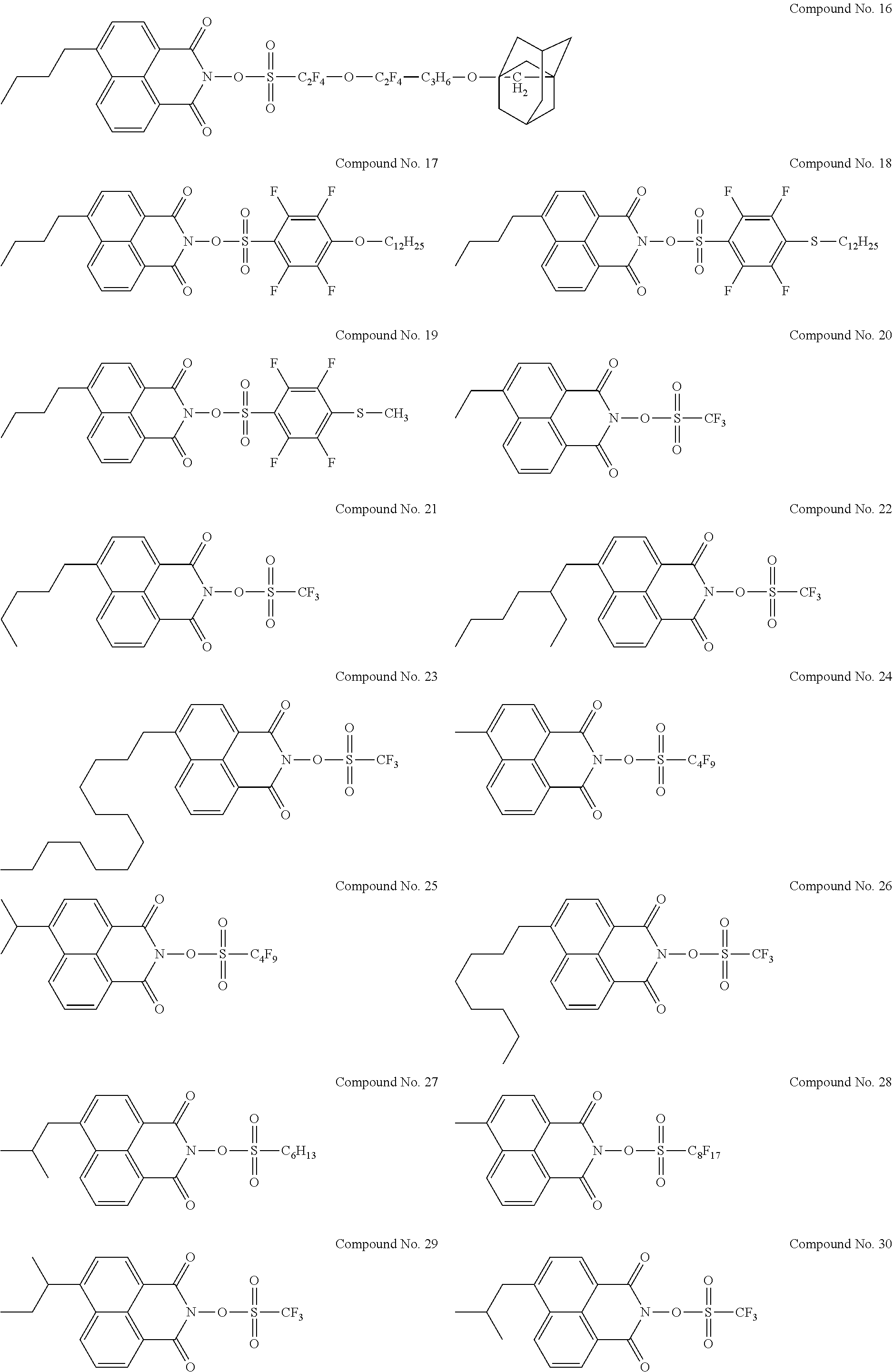

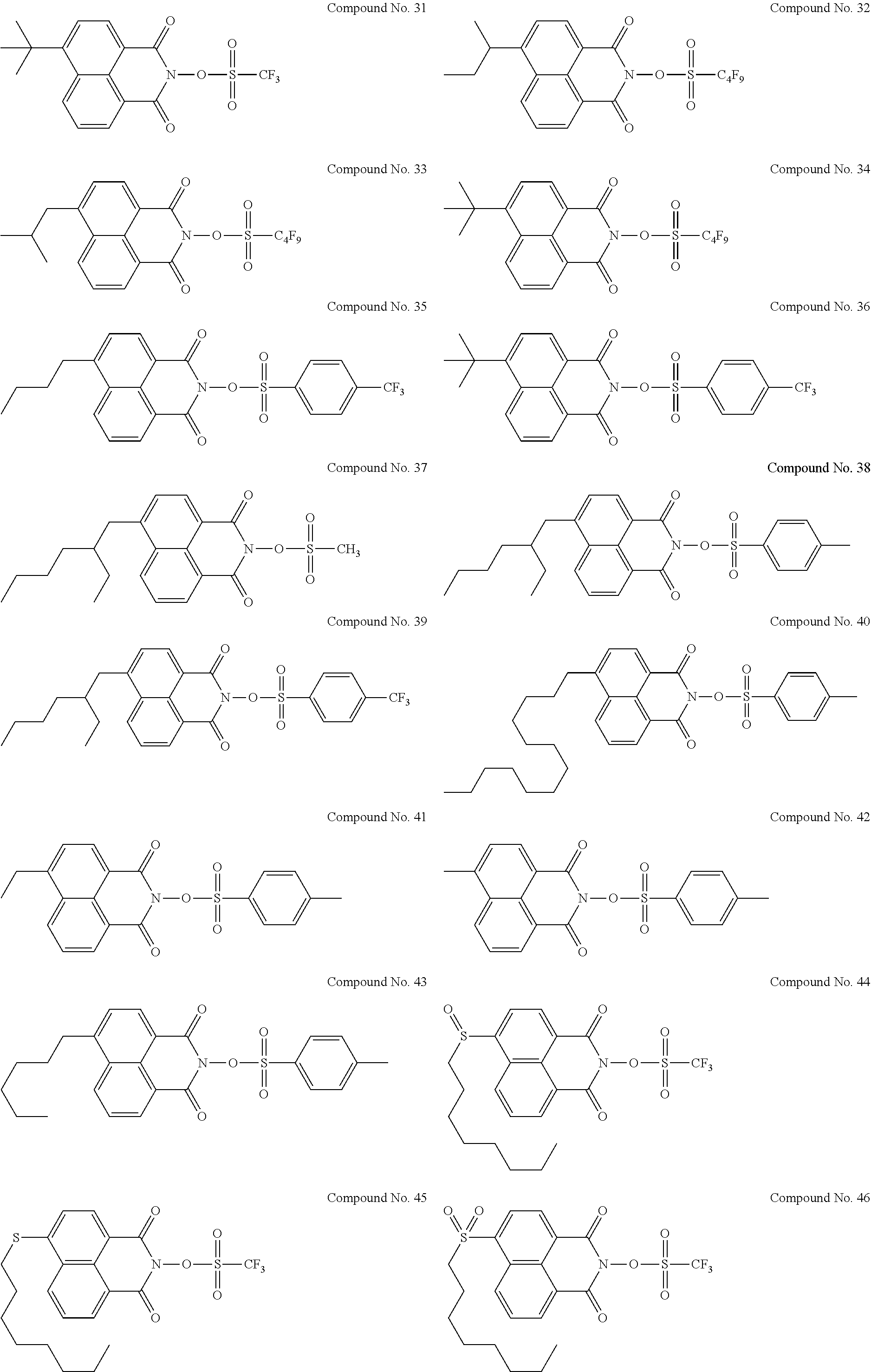

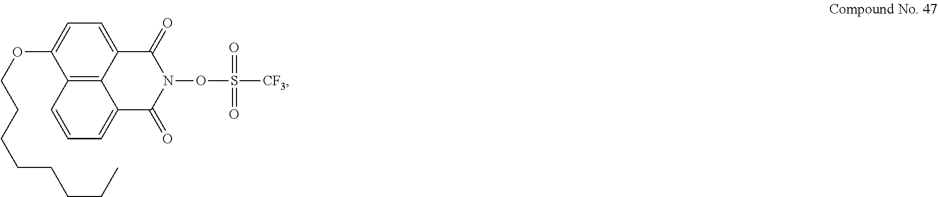 [SMILES: CCCCCCCCOc1ccc2c3c(cccc13)C(=O)N(OS(=O)(=O)C(F)(F)F)C2=O]

In Formula (I), R¹ may be selected such that the sulfonic acid derivative compound (A) releases an organic sulfonic acid appropriate for the intended use; however, R¹ is preferably a perfluoroalkyl group having 1 to 8 carbon atoms since a high acid strength is attained, and R¹ is more preferably a trifluoromethyl group, a pentafluoroethyl group, a heptafluoropropyl group, or a nonafluorobutyl group.

A method of producing the sulfonic acid derivative compound (A) represented by Formula (I) is not particularly restricted, and a well-known chemical reaction can be applied to synthesize the sulfonic acid derivative compound (A). For example, a method of synthesizing a sulfonic acid derivative compound using a bromide as a starting substance in the below-described manner can be employed.

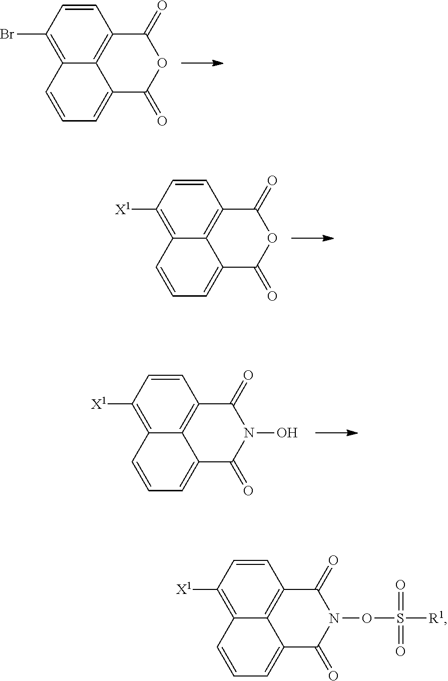

where X and R each represent the same group as in the above-described Formula (I).

In the negative photosensitive composition of the present invention, an amount of the sulfonic acid derivative compound (A) represented by Formula (I) is preferably 0.01 to 20 parts by mass, more preferably 0.5 to 10 parts by mass, with respect to 100 parts by mass of components other than a solvent of the polymer compound (B). When the amount of the sulfonic acid derivative compound (A) is less than 0.01 parts by mass, sensitivity and developability may be deteriorated, whereas when this amount is greater than 20 parts by mass, transparency to radiation is reduced, which can make it difficult to obtain a rectangular resist pattern.

### <Polymer Compound (B)>

In the crosslinkable functional group-containing polymer compound (B) that is contained in negative photosensitive composition of the present invention, examples of the crosslinkable functional group include a hydroxy group, an epoxy group, and a carboxyl group. The polymer compound (B) is not particularly restricted, and any known alkali-soluble resin can be used; however, a polyhydroxystyrene resin, an epoxy resin, an epoxy acrylate resin having at least one substituent selected from a hydroxy group and a carboxyl group, or a novolac resin having a hydroxy group, an epoxy group or a carboxyl group is preferred since such a resin is readily available and can attain high heat resistance.

Examples of the polyhydroxystyrene resin include polymers required to contain a structural unit represented by the following Formula (III):

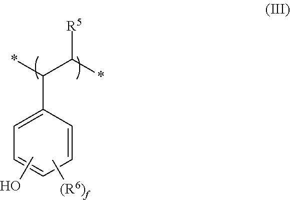

In Formula (III), R⁵ represents a hydrogen atom or a methyl group; R⁶ represents an alkyl group having 1 to 4 carbon atoms, an alkoxy group having 1 to 4 carbon atoms, or an alkoxycarbonyl group having 2 to 4 carbon atoms; f represents a number of 0 to 4; and the asterisks “*” indicate that this group is bound with adjacent groups at the * parts.

In Formula (III), examples of the alkyl group having 1 to 4 carbon atoms and alkoxy group having 1 to 4 carbon atoms that may be represented by R⁶ include the same groups as those described above for R¹ in Formula (I), and examples of the alkoxycarbonyl group having 2 to 4 carbon atoms include acetyloxy, propionyloxy, and butanoyloxy.

The polymer compound (B) used in the present invention may be a homopolymer composed of one selected from structural units represented by Formula (III), a copolymer composed of two or more selected from structural units represented by Formula (III), or a copolymer containing a structural unit that does not correspond to Formula (III).

The homopolymer composed of one selected from structural units represented by Formula (III) or the copolymer composed of two or more selected from structural units represented by Formula (III) can be obtained by homopolymerizing or copolymerizing hydroxystyrene or a derivative thereof.

The copolymer containing a structural unit that does not correspond to Formula (III) can be obtained by copolymerizing one or more selected from hydroxystyrene and derivatives thereof with the below-described ethylenically unsaturated monomer.

Examples of the ethylenically unsaturated monomer include unsaturated aliphatic hydrocarbons, such as ethylene, propylene, butylene, isobutylene, cycloolefin, vinyl chloride, vinylidene chloride, vinylidene fluoride, tetrafluoroethylene, vinylnorbornene, vinyltrimethylsilane, and vinyltrimethoxysilane; (meth)acrylic acid, a-chloroacrylic acid, itaconic acid, maleic acid, citraconic acid, fumaric acid, himic acid, crotonic acid, isocrotonic acid, vinylacetic acid, allylacetic acid, cinnamic acid, sorbic acid, mesaconic acid, trimellitic acid, mono[2-(meth)acryloyloxyethyl]succinate, mono[2-(meth)acryloyloxyethyl]phthalate, and mono(meth)acrylates of a polymer having a carboxyl group and a hydroxyl group at both terminals, such as ω-carboxypolycaprolactone mono(meth)acrylate; unsaturated polybasic acids, such as hydroxyethyl (meth)acrylate-malate, hydroxypropyl (meth)acrylate-malate, dicyclopentadiene-malate, and polyfunctional (meth)acrylates having one carboxyl group and two or more (meth)acryloyl groups; esters formed between an unsaturated monobasic acid and a polyhydric alcohol or a polyhydric phenol, such as 2-hydroxyethyl (meth)acrylate, 2-hydroxypropyl (meth)acrylate, glycidyl (meth)acrylate, the below-described Compound Nos. A1 to A4, methyl (meth)acrylate, butyl (meth)acrylate, isobutyl (meth)acrylate, t-butyl (meth)acrylate, cyclohexyl (meth)acrylate, n-octyl (meth)acrylate, isooctyl (meth)acrylate, isononyl (meth)acrylate, stearyl (meth)acrylate, lauryl (meth)acrylate, methoxyethyl (meth)acrylate, dimethylaminomethyl (meth)acrylate, dimethylaminoethyl (meth)acrylate, aminopropyl (meth)acrylate, dimethylaminopropyl (meth)acrylate, ethoxyethyl (meth)acrylate, poly(ethoxy)ethyl (meth)acrylate, butoxyethoxyethyl (meth)acrylate, ethylhexyl (meth)acrylate, phenoxyethyl (meth)acrylate, tetrahydrofuryl (meth)acrylate, vinyl (meth)acrylate, allyl (meth)acrylate, benzyl (meth)acrylate, ethylene glycol di(meth)acrylate, diethylene glycol di(meth)acrylate, triethylene glycol di(meth)acrylate, polyethylene glycol di(meth)acrylate, propylene glycol di(meth)acrylate, 1,4-butanediol di(meth)acrylate, 1,6-hexanediol di(meth)acrylate, trimethylolethane tri(meth)acrylate, trimethylolpropane tri(meth)acrylate, dipentaerythritol hexa(meth)acrylate, dipentaerythritol penta(meth)acrylate, pentaerythritol tetra(meth)acrylate, pentaerythritol tri(meth)acrylate, tricyclodecane dimethylol di(meth)acrylate, tri[(meth)acryloylethyl]isocyanurate, and polyester (meth)acrylate oligomers; metal salts of unsaturated polybasic acids, such as zinc (meth)acrylate and magnesium (meth)acrylate; unsaturated polybasic acid anhydrides, such as maleic anhydride, itaconic anhydride, citraconic anhydride, methyltetrahydrophthalic anhydride, tetrahydrophthalic anhydride, trialkyltetrahydrophthalic anhydrides, 5-(2,5-dioxotetrahydrofuryl)-3-methyl-3-cyclohexene-1,2-dicarboxylic acid anhydride, trialkyltetrahydrophthalic anhydride-maleic anhydride adducts, dodecenylsuccinic anhydride, and methylhimic anhydride; amides formed by an unsaturated monobasic acid and a polyfunctional amine, such as (meth)acrylamide, methylene-bis(meth)acrylamide, diethylenetriamine-tris(meth)acrylamide, xylylene-bis(meth)acrylamide, a-chloroacrylamide, and N-2-hydroxyethyl (meth)acrylamide; unsaturated aldehydes, such as acrolein; unsaturated nitriles, such as (meth)acrylonitrile, a-chloroacrylonitrile, vinylidene cyanide, and allyl cyanide; unsaturated aromatic compounds, such as styrene, 4-methylstyrene, 4-ethylstyrene, 4-methoxystyrene, 4-hydroxystyrene, 4-chlorostyrene, 4-acetoxystyrene, divinylbenzene, vinyltoluene, vinylbenzoic acid, vinylphenol, vinylsulfonic acid, 4-vinylbenzenesulfonic acid, vinylbenzyl methyl ether, vinylbenzyl glycidyl ether, vinylbenzyl chloride, 2-vinylnaphthalene, vinylanthracene, vinylaniline, vinylbenzoate, isopropenyl phenol, and propenyl phenol; unsaturated heterocyclic compounds, such as N-vinylpyrrolidone, 1-vinylimidazole, 2-vinylpyridine, N-vinyllactam, 9-vinylcarbazole, maleimide, N-phenylmaleimide, and N-cyclohexylmaleimide; unsaturated ketones, such as methyl vinyl ketone; unsaturated amine compounds, such as vinylamine, allylamine, N-vinylpyrrolidone, and vinylpiperidine; vinyl alcohols, such as allyl alcohol and crotyl alcohol; vinyl ethers, such as vinylmethyl ether, vinylethyl ether, n-butylvinyl ether, isobutylvinyl ether, and allyl glycidyl ether; indenes, such as indene and 1-methylindene; aliphatic conjugated dienes, such as 1,3-butadiene, isoprene, and chloroprene; macromonomers having a mono(meth)acryloyl group at a terminal of a polymeric molecular chain, such as polystyrene, polymethyl (meth)acrylate, poly-n-butyl (meth)acrylate, and polysiloxanes; vinyl chloride; vinylidene chloride; divinyl succinate; diallyl phthalate; triallyl phosphate; triallyl isocyanurate; vinyl thioether; vinylimidazole; vinyloxazoline; vinylcarbazole; vinylpyrrolidone; vinylpyridine; vinylurethane compounds formed by a hydroxy group-containing vinyl monomer and a polyisocyanate compound; vinylepoxy compounds formed by a hydroxy group-containing vinyl monomer and a polyepoxy compound; and epoxy acrylate compounds.

Thereamong, mono(meth)acrylates of a polymer having a carboxyl group and a hydroxyl group at both terminals, polyfunctional (meth)acrylates having one carboxyl group and two or more (meth)acryloyl groups, and esters formed between an unsaturated monobasic acid and a polyhydric alcohol or a polyhydric phenol are preferred.

These polymerizable compounds may be used individually or in combination of two or more thereof and, when two or more polymerizable compounds are used in combination, they may be copolymerized in advance to be used as a copolymer.

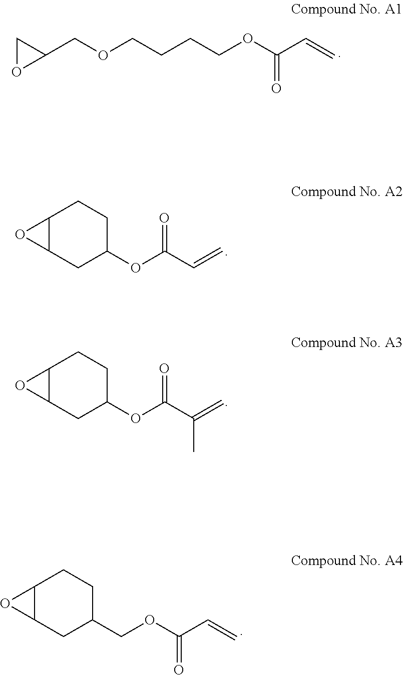

In the polymer compound (B) required to contain a structural unit represented by Formula (III), the content of the structural unit represented by Formula (III) is 40 to 100% by mole, preferably 50 to 90% by mole.

In the polymer compound (B), examples of the structural unit that does not correspond to Formula (III) include the followings:

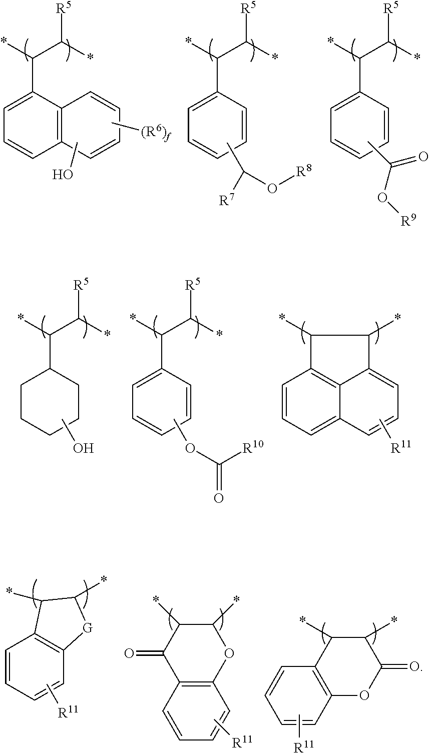

In the above-described formulae, R⁷ represents an alkyl group having 1 to 4 carbon atoms and R⁸ represents an alkyl group having 1 to 6 carbon atoms or a cycloalkyl group having 5 to 7 carbon atoms, or R⁷ and R⁸ are bound with each other to form a trimethylene chain or a tetramethylene chain; R⁹ represents a hydrocarbon group having 1 to 20 carbon atoms; R¹⁰ represents a hydrocarbon group having 1 to 10 carbon atoms; R¹¹ represents a hydrogen atom, an unsubstituted or halogen atom-substituted alkyl group having 1 to 20 carbon atoms, a hydroxy group, an alkoxy group having 1 to 20 carbon atoms, an alkanoyl group having 2 to 20 carbon atoms, an alkoxycarbonyl group having 2 to 20 carbon atoms, an aryl group having 6 to 10 carbon atoms, or a halogen atom; G represents methylene, an oxygen atom, or a sulfur atom; and R⁵, R⁶, f and * have the same meanings as in Formula (III).

The above-described epoxy resin or the above-described epoxy acrylate resin or epoxy methacrylate resin that has at least one substituent selected from a hydroxy group and a carboxyl group is not particularly restricted and any known such resin can be used; however, an epoxy acrylate resin or epoxy methacrylate resin that has a structure in which acrylic acid or methacrylic acid is added to a polyfunctional epoxy resin, or an epoxy acrylate resin or epoxy methacrylate resin that is obtained by an esterification reaction between a polybasic acid anhydride and an epoxy adduct having a structure in which acrylic acid or methacrylic acid is added to a polyfunctional epoxy resin, is preferred such a resin is readily available and can attain high sensitivity and high heat resistance.

As the polyfunctional epoxy resin, at least one compound selected from the group consisting of bisphenol-type epoxy compounds and glycidyl ethers is preferably used since a negative photosensitive composition having more favorable properties can thereby be obtained.

As the bisphenol-type epoxy compounds, in addition to epoxy compounds represented by the following Formula (IV), bisphenol-type epoxy compounds such as hydrogenated bisphenol-type epoxy compounds can be used as well.

As the glycidyl ethers, for example, ethylene glycol diglycidyl ether, propylene glycol diglycidyl ether, 1,4-butanediol diglycidyl ether, 1,6-hexanediol diglycidyl ether, 1,8-octanediol diglycidyl ether, 1,10-decanediol diglycidyl ether, 2,2-dimethyl-1,3-propanediol diglycidyl ether, diethylene glycol diglycidyl ether, triethylene glycol diglycidyl ether, tetraethylene glycol diglycidyl ether, hexaethylene glycol diglycidyl ether, 1,4-cyclohexane dimethanol diglycidyl ether, 1,1,1-tri(glycidyloxymethyl)propane, 1,1,1-tri(glycidyloxymethyl)ethane, 1,1,1-tri(glycidyloxymethyl)methane, and 1,1,1,1-tetra(glycidyloxymethyl)methane can be used.

In addition, alicyclic epoxy compounds, such as 3,4-epoxy-6-methylcyclohexylmethyl-3,4-epoxy-6-methylcyclohexane carboxylate, 3,4-epoxycyclohexylmethyl-3,4-epoxycyclohexane carboxylate, and 1-epoxyethyl-3,4-epoxycyclohexane; glycidyl esters, such as diglycidyl phthalate, diglycidyl tetrahydrophthalate, and glycidyl dimerate; glycidylamines, such as tetraglycidyl diaminodiphenylmethane, triglycidyl p-aminophenol, and N,N-diglycidylaniline; heterocyclic epoxy compounds, such as 1,3-diglycidyl-5,5-dimethylhydantoin and triglycidyl isocyanurate; dioxide compounds, such as dicyclopentadiene dioxide; naphthalene-type epoxy compounds; triphenylmethane-type epoxy compounds; and dicyclopentadiene-type epoxy compounds can be used as well.

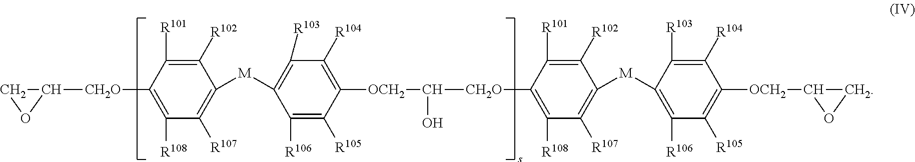

In this Formula, M represents a direct bond, a methylene group, an alkylidene group having 1 to 4 carbon atoms, an alicyclic hydrocarbon group, O, S, SO₂, SS, SO, CO, OCO, or a substituent selected from the group consisting of Formulae (IV-1), (IV-2) and (IV-3) below; R¹⁰¹, R¹⁰², R¹⁰³, R¹⁰⁴, R¹⁰⁵, R¹⁰⁶, R¹⁰⁷ and R¹⁰⁸ each independently represent a hydrogen atom, an alkyl group having 1 to 10 carbon atoms, an alkoxy group having 1 to 10 carbon atoms, or a halogen atom; and s represents a number of 0 to 10.

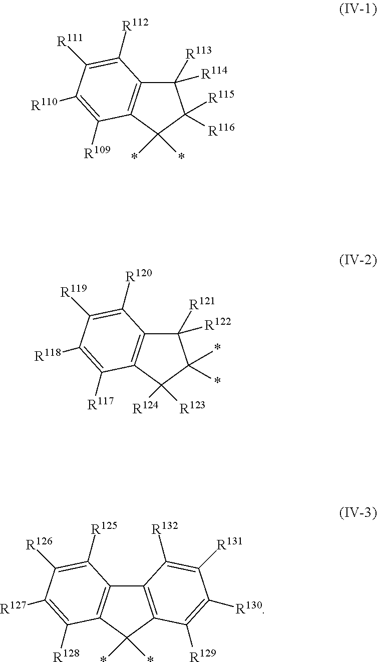

In these Formulae, R¹⁰⁹, R¹¹⁰, R¹¹¹, R¹¹², R¹¹³, R¹¹⁴, R¹¹⁵, R¹¹⁶, R¹¹⁷, R¹¹⁸, R¹¹⁹, R¹²⁰, R¹²¹, R¹²², R¹²³, R¹²⁴, R¹²⁵, R¹²⁶, R¹²⁷, R¹²⁸, R¹²⁹, R¹³⁰, R¹³¹ and R¹³² each independently represent a hydrogen atom, an alkyl group having 1 to 10 carbon atoms, an alkoxy group having 1 to 10 carbon atoms, an aryl group having 6 to 20 carbon atoms, an arylalkyl group having 7 to 20 carbon atoms, a heterocycle-containing group having 2 to 20 carbon atoms, or a halogen atom; alkylene moieties of the alkyl group and the arylalkyl group are optionally interrupted by an unsaturated bond, —O—, or —S—; and R¹⁰⁹, R¹¹⁰, R¹¹¹, R¹¹², R¹¹⁷, R¹¹⁸, R¹¹⁹, R¹²⁰, R¹²⁵, R¹²⁶, R¹²⁷, R¹²⁸, R¹²⁹, R¹³⁰, R¹³¹ and R¹³², which are adjacent, are optionally bound with each other to form a ring. It is noted here that the asterisks “*” indicate that each substituent is bound with adjacent groups at the * parts.

Examples of the above-described polybasic acid anhydride that is allowed to act after the above-described unsaturated monobasic acid include biphenyltetracarboxylic acid dianhydride, tetrahydrophthalic anhydride, succinic anhydride, biphthalic anhydride, maleic anhydride, trimellitic anhydride, pyromellitic anhydride, 2,2′,3,3′-benzophenonetetracarboxylic anhydride, ethylene glycol bis-anhydrotrimellitate, glycerol tris-anhydrotrimellitate, hexahydrophthalic anhydride, methyltetrahydrophthalic anhydride, nadic anhydride, methylnadic anhydride, trialkyltetrahydrophthalic anhydrides, hexahydrophthalic anhydride, 5-(2,5-dioxotetrahydrofuryl)-3-methyl-3-cyclohexene-1,2-dicarboxylic anhydride, trialkyltetrahydrophthalic anhydride-maleic anhydride adducts, dodecenylsuccinic anhydride, and methylhymic anhydride.

The reaction molar ratio of the above-described epoxy compound, unsaturated monobasic acid and polybasic acid anhydride is preferably as follows.

That is, the epoxy adduct compound is preferably added such that the ratio of the carboxyl group of the unsaturated monobasic acid is 0.1 to 1.0 with respect to one epoxy group of the epoxy compound, and the ethylenically unsaturated compound is preferably added such that the ratio of the acid anhydride structure of the polybasic acid anhydride is 0.1 to 1.0 with respect to one hydroxy group of the epoxy adduct. The reaction between the epoxy compound, the unsaturated monobasic acid and the polybasic acid anhydride can be performed in accordance with a conventional method.

As the above-described novolac resin having a hydroxy group, an epoxy group or a carboxyl group, any conventionally known one can be used.

A novolac resin can be usually obtained by condensation of a phenolic compound and an aldehyde in the presence of an acid catalyst. Examples of the phenolic compound used in the production of a novolac resin include phenol, o-, m- or p-cresol, 2,3-, 2,5-, 3,4- or 3,5-xylenol, 2,3,5-trimethylphenol, 2-, 3- or 4-tert-butylphenol, 2-tert-butyl-4- or -5-methylphenol, 2-, 4- or 5-methylresorcinol, 2-, 3- or 4-methoxyphenol, 2,3-, 2,5- or 3,5-dimethoxyphenol, 2-methoxyresorcinol, 4-tert-butylcatechol, 2-, 3- or 4-ethylphenol, 2,5- or 3,5-diethylphenol, 2,3,5-triethylphenol, 2-naphthol, 1,3-, 1,5- or 1,7-dihydroxynaphthalene, and a polyhydroxytriphenylmethane compound obtained by condensation of xylenol and hydroxybenzaldehyde. These phenolic compounds may be used individually, or two or more thereof may be used in combination.

Examples of the aldehyde used in the production of a novolac resin include aliphatic aldehydes, such as formaldehyde, acetaldehyde, propionaldehyde, butyraldehyde, isobutyraldehyde, pivalaldehyde, hexylaldehyde, acroleinaldehyde, and crotonaldehyde; alicyclic compounds, such as cyclohexyaldehyde, cyclopentanealdehyde, furfural, and furyl acrolein; aromatic aldehydes, such as benzaldehyde, o-, m-, orp-methylbenzaldehyde, p-ethylbenzaldehyde, 2,4-, 2,5-, 3,4- or 3,5-dimethylbenzaldehyde, o-, m- or p-hydroxybenzaldehyde, o-, m- or p-anisaldehyde, and vanillin; and aromatic aliphatic aldehydes, such as phenyl acetaldehyde and cinnamaldehyde. These aldehydes may also be used individually, or two or more thereof may be used in combination as desired. Among these aldehydes, formaldehyde is preferably used since it can be easily obtained industrially.

Examples of the acid catalyst used for the condensation of a phenolic compound and an aldehyde include inorganic acid, such as hydrochloric acid, sulfuric acid, perchloric acid, and phosphoric acid; organic acid, such as formic acid, acetic acid, oxalic acid, trichloroacetic acid, and p-toluenesulfonic acid; and divalent metal salts, such as zinc acetate, zinc chloride, and manganese acetate. These acid catalysts may also be used individually, or two or more thereof may be used in combination. The condensation reaction can be performed in accordance with a conventional method, for example, at a temperature in a range of 60 to 120° C. for a period of 2 to 30 hours or so.

As the polymer compound (B), in addition to the above-described compounds, for example, a polyvinyl phenol or a polyvinyl phenol in which some of its hydroxy groups are alkyl-etherified can be used, and a plurality thereof may be used in combination.

The polystyrene-equivalent weight-average molecular weight (Mw) of the polymer compound (B), which is determined by gel permeation chromatography (GPC), is usually 1,000 to 500,000, preferably 2,000 to 200,000, more preferably 3,000 to 100,000. In this case, when the Mw of the polymer compound (B) is less than 1,000, the heat resistance of a cured product of the negative photosensitive composition tends to be reduced, whereas when the Mw is higher than 500,000, the developability and the coatability of a cured product of the negative photosensitive composition tend to be deteriorated.

The content of the polymer compound (B) excluding its solvent is 1 to 50% by mass, preferably 3 to 20% by mass, with respect to a total amount of the components (A), (B) and (C).

### <Crosslinking Agent (C)>

As the crosslinking agent (C) contained in the composition of the present invention, any crosslinking agent can be used with no particular restriction as long as it is capable of reacting with the crosslinkable functional group of the polymer compound (B) and thereby curing the composition, and examples thereof include epoxy resins as well as amino resins having a hydroxyl group or an alkoxyl group, such as melamine resins, urea resins, guanamine resins, glycoluril-formaldehyde resins, succinylamide-formaldehyde resins, and ethylene urea-formaldehyde resins. As these crosslinking agents, melamine, urea, guanamine, glycoluril, succinylamide and ethylene urea that are each methylolated through reaction with formalin in boiling water, or the resultants thereof further alkoxylated through reaction with a lower alcohol, can be used.

The content of the crosslinking agent (C) is 0.5 to 50 parts by mass, preferably 1 to 30 parts by mass, with respect to 100 parts by mass of the polymer compound (B).

The composition of the present invention is particularly useful as a chemically amplified resist. By the action of an acid generated from a photoacid generator containing the sulfonic acid derivative compound represented by Formula (I) upon exposure, the composition of the present invention is made soluble in a developing solution through a polarity change induced by a deprotection reaction of a polymer side chain, such as cleavage of a chemical bond of an ester group, an acetal group or the like.

### <Optional Component (D)>

In the composition of the present invention, a photoacid generator other than the sulfonic acid derivative compound (A) used in the present invention may be used as an optional component (D). Examples of such other photoacid generator include iodonium salt compounds and sulfonium compounds and, when such other photoacid generator is used in combination, the amount thereof is preferably 10 to 200 parts by mass with respect to 100 parts by mass of the sulfonic acid derivative compound used in the present invention.

In the negative photosensitive composition of the present invention, various additives may be incorporated as well. Examples of the various additives include various resin additives, such as a base quencher, an acid amplifier, a base generator, a dissolution inhibitor, a basic compound, an inorganic filler, an organic filler, a coloring agent (e.g., a pigment or a dye), an antifoaming agent, a thickening agent, a flame retardant, an antioxidant, a stabilizer, and a leveling agent. In the composition of the present invention, these additives are used in a total amount of preferably 50% by mass or less.

In the negative photosensitive composition of the present invention, in order to facilitate dissolution of the sulfonic acid derivative compound (A) used in the present invention, the sulfonic acid derivative compound (A) can be dissolved in an appropriate solvent, such as propylene carbonate, carbitol, carbitol acetate, butyrolactone or propylene glycol-1-monomethylether-2-acetate, in advance prior to its use.

The negative photosensitive composition of the present invention is, prior to its use, normally adjusted by being dissolved in a solvent such that a total amount of the components (A), (B) and (C) is usually 5 to 50% by mass, preferably 10 to 25% by mass, with respect to the total amount of the composition, and subsequently filtered through, for example, a filter having a pore size of about 0.2 μm. The negative photosensitive composition of the present invention can be prepared by a method of, for example, mixing, dissolving or kneading the components (A), (B), (C) and (D).

The negative photosensitive composition of the present invention can be cured by irradiating thereto heat or light. A light source used for exposure of the negative photosensitive composition is selected as appropriate from those emitting g-line (436 nm), h-line (405 nm), i-line (365 nm), DUV (248 nm), visible light, ultraviolet radiation, far-ultraviolet radiation, X-ray, charged particle beam, electron beam, ion beam or the like in accordance with the type of the photoacid generator to be used.

The negative photosensitive composition of the present invention is coated on a substrate made of silicon or the like by an appropriate coating method using a spinner, a coater or the like, subsequently exposed through a prescribed mask, post-baked for improvement of the apparent sensitivity of the resulting resist and then developed, whereby a more favorable resist pattern can be obtained.

Specific examples of the applications of the negative photosensitive composition of the present invention include, but not particularly limited to: optical filters; paints; coating agents; lining agents; adhesives; printing plates; insulating varnishes; insulation sheets; laminated plates; printed circuit boards; sealants for semiconductor devices, LED packages, liquid crystal inlets, organic EL devices, optical elements, electrical insulating materials, electronic components, separation membranes and the like; molded materials; putties; glass fiber impregnants; fillers; passivation films for semiconductors, solar cells and the like; interlayer insulation films and surface protection films that are used in thin-film transistors (TFT), liquid crystal displays, organic EL displays, printed boards and the like; color filters of printed boards, color televisions, PC monitors, personal digital assistants and CCD image sensors; electrode materials for plasma display panels; printing inks; dental compositions; resins for stereolithography; liquid-form films and dry films; micromachine components; glass fiber cable coatings; materials for holographic recording; magnetic recording materials; optical switches; plating masks; etching masks; screen printing stencils; touch panels such as transparent conductive films; MEMS elements; nanoimprint materials; photofabrication applications, such as two-dimensional and three-dimensional high-density mounting and the like of semiconductor packages; decoration sheets; artificial nails; glass-alternative optical films; electronic papers; optical disks; micro-lens arrays used in projectors, optical communication lasers and the like; prism lens sheets used in backlights of liquid crystal displays; Fresnel lens sheets used in the screens of projection televisions and the like; lens parts of lens sheets such as lenticular lens sheets; backlights and the like using such sheets; optical lenses, such as microlenses and image pickup lenses; optical elements; optical connectors; optical waveguides; insulation packings; heat-shrinkable rubber tubes; O-rings; sealing agents for display devices; protective materials; optical fiber protection materials; adhesives; die bonding agents; high heat radiation materials; high-heat-resistant sealing materials; members for solar cells, fuel cells and secondary batteries; solid electrolytes for batteries; insulation coating materials; heat-sensitive drums for copying machines; gas separation membranes; civil engineering and construction materials, such as concrete protecting materials, linings, soil injection agents, sealing agents, cold-heat storage materials, glass coatings and foams; medical materials, such as tube/seal materials, coating materials, sealing materials for sterilizers, contact lenses, oxygen enrichment membranes, and biochips; automobile components; and various mechanical components.

### Examples

The present invention will now be described in more detail by way of Examples and Comparative Examples; however, the present invention is not restricted thereto.

### Examples 1 and 2, and Comparative Examples 1 to 10

### (Preparation of Negative Photosensitive Compositions and Production of Negative Resist Films)

Compositions were each prepared in accordance with the formulations shown in [Table 1] and [Table 2]. The unit of the amounts shown in these Tables is parts by mass. The compositions shown in [Table 1] and [Table 2] were each filtered through a 1-μm microfilter and spin-coated (2,000 rpm, 7 seconds) on a glass substrate such that the resulting film would have a thickness of 5.0 μm after pre-baking. Subsequently, the resultants were pre-baked on a hot plate at 110° C. for 180 seconds, whereby negative resist films were obtained.

The negative resist films obtained in Examples 1 and 2 and Comparative Examples 1 to 10 were each exposed using a high-pressure mercury lamp and subsequently subjected to 120-second PEB (Post-Exposure Baking) at 120° C. and development in a 2.38% aqueous tetramethylammonium hydroxide solution. Thereafter, the resultants were post-baked at 230° C. for 30 minutes.

### (Sensitivity)

After the post-baking, the film thickness was measured, and the residual film ratio (film thickness after post-baking/initial film thickness) was determined. The results thereof are shown in [Table 1] and [Table 2]. As for the evaluation, an evaluation of ∘ was given when the exposure dose resulting in a residual film ratio of 80% or higher was less than 20 mJ/cm², and an evaluation of x was given when this exposure dose was 20 mJ/cm² or higher.

TABLE 1

| | | | Comparative | Comparative | Comparative | Comparative | Comparative |
|---|---|---|---|---|---|---|---|
| | | Example 1 | Example 1 | Example 2 | Example 3 | Example 4 | Example 5 |
| A | A-1 | 0.57 | 0.57 | — | — | — | — |
| | A′-1 | — | — | 0.57 | 0.57 | — | — |
| | A′-2 | — | — | — | — | 0.57 | 0.57 |
| B | B-1 | 81.49 | — | 81.49 | — | 81.49 | — |
| | B′-1 | — | 81.49 | — | 81.49 | — | 81.49 |
| C | C-1 | 2.85 | 2.85 | 2.85 | 2.85 | 2.85 | 2.85 |
| D | D-1 | 5.70 | 5.70 | 5.70 | 5.70 | 5.70 | 5.70 |
| E | E-1 | 9.39 | 9.39 | 9.39 | 9.39 | 9.39 | 9.39 |

| | | | | | | |
|---|---|---|---|---|---|---|
| Sensitivity | ∘ | x | x | x | x | x |

TABLE 2

| | | | Comparative | Comparative | Comparative | Comparative | Comparative |
|---|---|---|---|---|---|---|---|
| | | Example 2 | Example 6 | Example 7 | Example 8 | Example 9 | Example 10 |
| A | A-1 | 0.85 | 0.85 | — | — | — | — |
| | A′-1 | — | — | 0.85 | 0.85 | — | — |
| | A′-2 | — | — | — | — | 0.85 | 0.85 |
| B | B-2 | 80.77 | — | 80.77 | — | 80.77 | — |
| | B′-1 | — | 80.77 | — | 80.77 | — | 80.77 |
| C | C-1 | 2.83 | 2.83 | 2.83 | 2.83 | 2.83 | 2.83 |
| D | D-1 | 5.65 | 5.65 | 5.65 | 5.65 | 5.65 | 5.65 |
| E | E-1 | 9.90 | 9.90 | 9.90 | 9.90 | 9.90 | 9.90 |

| | | | | | | |
|---|---|---|---|---|---|---|
| Sensitivity | ∘ | x | x | x | x | x |

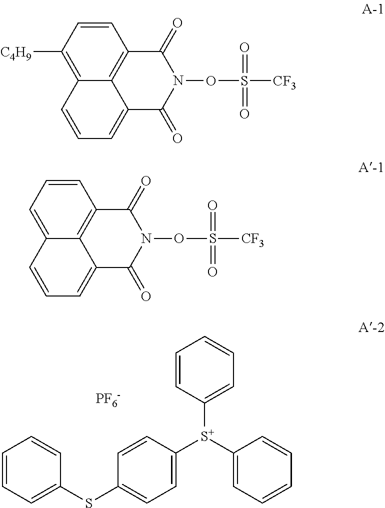

B-1: a 35% PGMEA solution of a copolymer resin (Mw=12,000) obtained by polymerizing p-hydroxystyrene and styrene at a ratio of 85:15

B-2: a 35% PGMEA solution of a novolac resin (Mw=12,000) obtained by polymerizing p-cresol and m-cresol at a ratio of 50:50

B′-1: SPC-1000 (acrylic resin, manufactured by Showa Denko K.K.)

C-1: NIKALAC MW-30 (methylated melamine resin, manufactured by Sanwa Chemical Co., Ltd.)

D-1: a 1% PGMEA solution of FZ-2122 (leveling agent, manufactured by Dow Corning Toray Co., Ltd.)

E-1: PGMEA

### Example 3 and Comparative Examples 11 and 12

### (Preparation of Negative Photosensitive Compositions and Production of Negative Resist Films)

Compositions were each prepared in accordance with the formulations shown in [Table 3]. The unit of the amounts shown in [Table 3] is parts by mass. The thus obtained compositions were each filtered through a 1-μm microfilter and spin-coated (6,000 rpm, 7 seconds) on a glass substrate such that the resulting film would have a thickness of 1.0 m after pre-baking. Subsequently, the resultants were pre-baked on a hot plate at 110° C. for 180 seconds, whereby negative resist films were obtained. The thus obtained negative resist films were each exposed at an exposure dose of 100 mJ/cm² using a high-pressure mercury lamp and subsequently subjected to 120-second PEB (Post-Exposure Baking) at 120° C., followed by 30-minute post-baking at 230° C.

### (Heat Resistance)

After the post-baking, the brightness (Y value) was measured. The results thereof are shown in [Table 3]. As for the evaluation, an evaluation of ∘ when the value of brightness change (ΔY) after the 30-minute heating at 230° C. was smaller than 3.0, and an evaluation of x was given when this value was 3.0 or larger.

| | | Example | Comparative | Comparative |
|---|---|---|---|---|
| | | 3 | Example 11 | Example 12 |
| A | A-1 | 0.50 | — | — |
| | A′-1 | — | 0.50 | — |
| | A′-2 | — | — | 0.50 |
| B | B-1 | 71.30 | 71.30 | 71.30 |
| C | C-1 | 2.50 | 2.50 | 2.50 |
| D | D-1 | 4.99 | 4.99 | 4.99 |
| E | E-1 | 20.71 | 20.71 | 20.71 |

| | | | |
|---|---|---|---|
| Heat | ∘ | x | x |
| resistance | | | |

From [Table 1] to [Table 3] above, the negative resists containing the sulfonic acid derivative compound according to the present invention were confirmed to exhibit higher sensitivity at the time of being cured and to yield cured articles having higher heat resistance as compared to the negative resists containing the respective comparative compounds.

1-9. (canceled)

10. A negative photosensitive composition comprising:
a sulfonic acid derivative compound (A) represented by the following Formula (I): 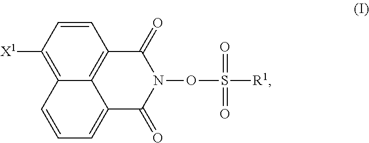
where X¹ represents a linear or branched alkyl group having 1 to 14 carbon atoms; a methylene group in the alkyl group is optionally substituted with —S—, —O—, —SO— or —SO₂—; R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the following Formula (II): 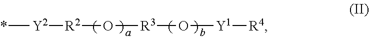
where Y¹ represents a single bond or an alkanediyl group having 1 to 4 carbon atoms; Y² represents a single bond, a sulfur atom, or an oxygen atom; R² and R³ each independently represent an alkanediyl group having 2 to 6 carbon atoms, a halogenated alkanediyl group having 1 to 6 carbon atoms, an arylene group having 6 to 20 carbon atoms, or a halogenated arylene group having 6 to 20 carbon atoms; R⁴ represents a linear or branched alkyl group having 1 to 18 carbon atoms, a linear or branched halogenated alkyl group having 1 to 18 carbon atoms, an alicyclic hydrocarbon group having 3 to 12 carbon atoms, an aryl group having 6 to 20 carbon atoms, a halogenated aryl group having 6 to 20 carbon atoms, an arylalkyl group having 7 to 20 carbon atoms, or a halogenated arylalkyl group having 7 to 20 carbon atoms; a and b each represent 0 or 1; either a or b is 1; and an asterisk “*” indicates that this group is bound with an adjacent group at the * part; and
the aliphatic hydrocarbon group having 1 to 18 carbon atoms, the aryl group having 6 to 20 carbon atoms, the arylalkyl group having 7 to 20 carbon atoms or the alicyclic hydrocarbon group having 3 to 12 carbon atoms has no substituent, or is optionally substituted with a halogen atom or a group selected from a halogenated alkyl group having 1 to 4 carbon atoms, an alkoxy group having 1 to 18 carbon atoms and an alkylthio group having 1 to 18 carbon atoms;
a crosslinkable functional group-containing polymer compound (B); and
a crosslinking agent (C).

11. The negative photosensitive composition according to claim 10, wherein X¹ is an alkyl group having 3 to 8 carbon atoms.

12. The negative photosensitive composition according to claim 10, wherein X¹ is an alkyl group having 4 carbon atoms.

13. The negative photosensitive composition according to claim 10, wherein R¹ is a perfluoroalkyl group having 1 to 8 carbon atoms.

14. The negative photosensitive composition according to claim 10, wherein the crosslinkable functional group-containing polymer compound (B) is a polyhydroxystyrene resin, an epoxy resin, an epoxy acrylate resin or epoxy methacrylate resin having at least one substituent selected from a hydroxy group and a carboxyl group, or a novolac resin having a hydroxy group, an epoxy group or a carboxyl group.

15. The negative photosensitive composition according to claim 10, wherein the crosslinkable functional group-containing polymer compound (B) is a polyhydroxystyrene resin required to contain a structural unit represented by the following Formula (III): 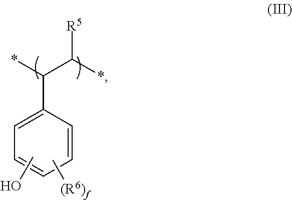
where R⁵ represents a hydrogen atom or a methyl group; R⁶ represents an alkyl group having 1 to 4 carbon atoms, an alkoxy group having 1 to 4 carbon atoms, or an alkoxycarbonyl group having 2 to 4 carbon atoms; f represents a number of 0 to 4; and asterisks “*” indicate that this group is bound with adjacent groups at the * parts.

16. The negative photosensitive composition according to claim 10, wherein the crosslinkable functional group-containing polymer compound (B) is an epoxy acrylate resin or epoxy methacrylate resin having a structure in which acrylic acid or methacrylic acid is added to a polyfunctional epoxy resin, or an epoxy acrylate resin or epoxy methacrylate resin obtained by an esterification reaction between a polybasic acid anhydride and an epoxy adduct having a structure in which acrylic acid or methacrylic acid is added to a polyfunctional epoxy resin.

17. The negative photosensitive composition according to claim 10, wherein the crosslinking agent (C) is a melamine resin.

18. A cured article obtained by curing the negative photosensitive composition according to claim 10.

19. The cured article according to claim 18, wherein X¹ is an alkyl group having 3 to 8 carbon atoms.

20. The cured article according to claim 18, wherein X¹ is an alkyl group having 4 carbon atoms.

21. The cured article according to claim 18, wherein R¹ is a perfluoroalkyl group having 1 to 8 carbon atoms.

22. The cured article according to claim 18, wherein the crosslinkable functional group-containing polymer compound (B) is a polyhydroxystyrene resin, an epoxy resin, an epoxy acrylate resin or epoxy methacrylate resin having at least one substituent selected from a hydroxy group and a carboxyl group, or a novolac resin having a hydroxy group, an epoxy group or a carboxyl group.

23. The cured article according to claim 18, wherein the crosslinking agent (C) is a melamine resin.

24. A curing method comprising curing the negative photosensitive composition according to claim 10 by irradiating thereto heat or light.

25. The curing method according to claim 24, wherein X¹ is an alkyl group having 3 to 8 carbon atoms.

26. The curing method according to claim 24, wherein X¹ is an alkyl group having 4 carbon atoms.

27. The curing method according to claim 24, wherein R¹ is a perfluoroalkyl group having 1 to 8 carbon atoms.

28. The curing method according to claim 24, wherein the crosslinkable functional group-containing polymer compound (B) is a polyhydroxystyrene resin, an epoxy resin, an epoxy acrylate resin or epoxy methacrylate resin having at least one substituent selected from a hydroxy group and a carboxyl group, or a novolac resin having a hydroxy group, an epoxy group or a carboxyl group.

29. The curing method according to claim 24, wherein the crosslinking agent (C) is a melamine resin.
